(19) United States
(12) Patent Application Publication
(10) Pub. No.: US 2026/0282915 A1
(43) Pub. Date: Sep. 17, 2026

(54) Semiconductor Device

(71) Applicant: Hitachi Astemo, Ltd., Hitachinaka-shi, Ibaraki (JP)

(72) Inventors: Hiromi SHIMAZU, Tokyo (JP); Takuro KANAZAWA, Hitachinaka-shi, Ibaraki (JP); Mitsutoshi TAMURA, Hitachinaka-shi, Ibaraki (JP); Hidehiko TAKAHARA, Hitachinaka-shi, Ibaraki (JP)

(21) Appl. No.: 18/878,786

(22) PCT Filed: May 15, 2023
(86) PCT No.: PCT/JP2023/018183

§ 371 Date: Dec. 24, 2024

(30) Foreign Application Priority Data
Jul. 4, 2022 (JP) 2022-108044

(51) Int. Cl. H10W 40/60; H10W 40/20

(52) U.S. Cl. CPC H10W 40/60; H10W 40/233

(57) ABSTRACT

A semiconductor device includes: a plurality of semiconductor modules each incorporating a power semiconductor element and having a heat dissipation surface; a radiator in thermal contact with the heat dissipation surfaces of the plurality of semiconductor modules arrayed in a line; and a fixing member that fixes the radiator so as to press the radiator against the heat dissipation surfaces, in which the radiator includes a heat dissipation base portion pressed against the heat dissipation surfaces of the semiconductor modules, and a plurality of fixing flange portions each having a cantilever shape formed along a direction of the array integrally with the heat dissipation base portion and having flexural rigidity smaller than flexural rigidity of the heat dissipation base, and the fixing member fixes the radiator so as to elastically deform the fixing flange portion and press the heat dissipation base portion against the heat dissipation surfaces of the semiconductor modules by an elastic force of the fixing flange portion.

### TECHNICAL FIELD

The present invention relates to a semiconductor device.

### BACKGROUND ART

In recent years, hybrid vehicles and electric vehicles have been widely used in order to reduce the load on the environment. In hybrid vehicles and electric vehicles, downsizing and cost reduction of components to be mounted are regarded as important, and semiconductor devices in power conversion devices are also no exception and downsizing and cost reduction are required. In order to downsize a semiconductor device having a large heat generation amount among electronic components constituting the power conversion device, it is necessary to improve cooling performance. Therefore, such a semiconductor device generally includes a cooling device such as a radiator or a cooler for cooling a semiconductor module incorporating a power semiconductor element.

For example, PTL 1 discloses a structure in which a semiconductor module incorporating a power semiconductor element is sandwiched between a pair of cooling pipes, and the cooling pipes are pressed against the semiconductor module by a pressing plate. By providing the pressing plate, a compressive force is generated on a contact surface between a heat dissipation surface of the semiconductor module and the cooling pipes, and the heat dissipation surface is brought into close contact with the cooling pipes. Furthermore, adhesion is improved by adopting a configuration in which the pressing plate is pressed against the semiconductor module by the biasing force of a spring member.

### CITATION LIST

### Patent Literature

PTL 1: JP 2009-182312 A

### SUMMARY OF INVENTION

### Technical Problem

However, in the technique of PTL 1, a pressing plate and a spring member are further required to secure the adhesion, and there are problems of an increase in the number of components and an increase in cost.

### Solution to Problem

A semiconductor device according to an aspect of the present invention includes: a plurality of semiconductor modules each incorporating a power semiconductor element and having a heat dissipation surface; a radiator in thermal contact with the heat dissipation surfaces of the plurality of semiconductor modules arrayed in a line; and a fixing member that fixes the radiator so as to press the radiator against the heat dissipation surfaces, in which the radiator includes a heat dissipation base portion pressed against the heat dissipation surfaces of the semiconductor modules, and a plurality of fixing flange portions each having a cantilever shape formed along a direction of the array integrally with the heat dissipation base portion and having flexural rigidity smaller than flexural rigidity of the heat dissipation base, and the fixing member fixes the radiator so as to elastically deform the fixing flange portion and press the heat dissipation base portion against the heat dissipation surfaces of the semiconductor modules by an elastic force of the fixing flange portion.

### Advantageous Effects of Invention

According to the present invention, it is possible to reduce the number of components and cost of the semiconductor device.

### BRIEF DESCRIPTION OF DRAWINGS

FIG. 1 is a plan view illustrating an example of a semiconductor device.

FIG. 2 is a circuit diagram illustrating an example of a circuit configuration of a power module.

FIG. 3 is a plan view illustrating an external shape of the power module.

FIG. 4 is a cross-sectional view taken along line B-B of FIG. 3.

FIG. 5 is a cross-sectional view taken along line A-A of FIG. 1.

FIG. 6 is a cross-sectional view taken along line C-C of FIG. 1.

FIG. 7A is a view illustrating a shape of a fixing flange before being coupled by a bolt and a nut.

FIG. 7B is a view illustrating a shape of the fixing flange after being coupled.

FIG. 8A is a plan view of a semiconductor device in a case where width dimensions of all fixing flanges are the same.

FIG. 8B is a view describing deformation of a radiator.

FIG. 9 is a view illustrating Modification 1.

FIG. 10 is a view illustrating Modification 2.

FIG. 11A is a plan view of a radiator in Modification 3.

FIG. 11B is a side view of the radiator in Modification 3.

FIG. 12A is a view illustrating another structure of Modification 3.

FIG. 12B is a view illustrating another structure of Modification 3.

FIG. 13A is a plan view illustrating Modification 4.

FIG. 13B is a view of a semiconductor device in Modification 4 as viewed laterally.

FIG. 14 is a view illustrating Modification 5.

FIG. 15 is a view illustrating Modification 6.

FIG. 16 is a view illustrating Modification 7.

### DESCRIPTION OF EMBODIMENTS

An embodiment for carrying out the present invention will be described below with reference to the drawings. The following description and drawings are illustrative for describing the present invention and are omitted and simplified as appropriate for a clearer description. In the following description, identical or similar elements and processing are denoted by identical reference sings, and redundant description may be omitted. Note that the content described below is merely an example of an embodiment of the present invention, and the present invention is not limited to the following embodiment and can be carried out in various other forms.

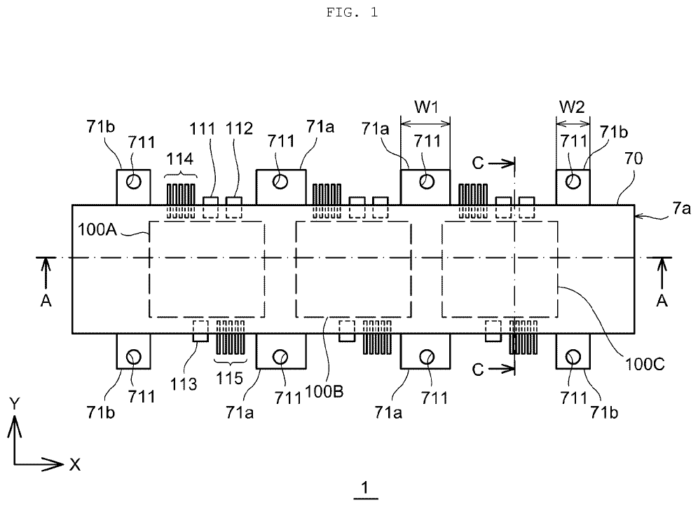

FIG. 1 is a plan view illustrating an example of a semiconductor device 1 of the present embodiment. Hereinafter, coordinate axes are set such that the longitudinal direction of the semiconductor device 1 is an X direction, the short direction of the semiconductor device 1 is a Y direction, and the height direction of the semiconductor device 1 is a Z direction. The semiconductor device 1 of the present embodiment is provided in an inverter circuit of a power conversion device mounted on an electric vehicle, a hybrid vehicle, or the like, for example. The power conversion device performs power conversion between a direct-current power supply and a vehicle traveling motor generator (e.g., a three-phase alternating-current type rotating electric machine). The power conversion device includes a smoothing capacitor and an inverter circuit that is a power converter. The inverter circuit converts the input direct-current power into a three-phase alternating current of a predetermined frequency, and outputs the three-phase alternating current to the motor generator. The semiconductor device 1 of FIG. 1 is provided in an inverter circuit and includes power modules 100A, 100B, and 100C for three phases.

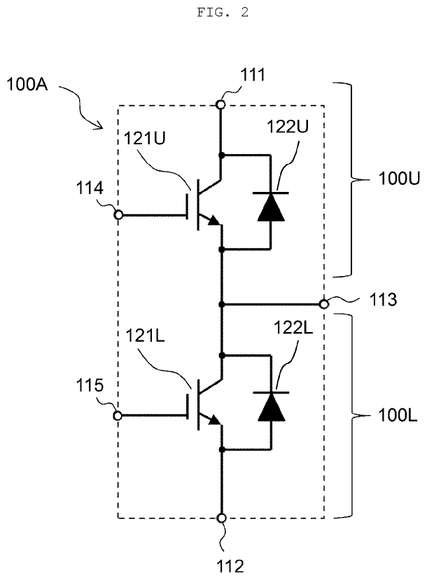

FIG. 2 is a circuit diagram illustrating an example of the circuit configuration of the power module 100A. Note that the power modules 100A to 100C have the identical configuration. The circuit of the power module 100A includes an upper arm 100U and a lower arm 100L connected in series. The upper arm 100U includes a power semiconductor element 121U and a diode 122U. The lower arm 100L includes a power semiconductor element 121L and a diode 122L. The power semiconductor elements 121U and 121L include, for example, an insulated gate bipolar transistor (IGBT) or a MOSFET. The power semiconductor element 121U of the upper arm 100U is controlled on/off by a control signal input to an upper arm control terminal 114. Similarly, the power semiconductor element 121L of the lower arm 100L is controlled on/off by a control signal input to a lower arm control terminal 115.

An external connection P terminal 111 of the upper arm 100U is connected to a high-potential power line of the direct-current power supply, and an external connection N terminal 112 of the lower arm 100L is connected to a low-potential power line of the direct-current power supply. An external connection AC terminal 113 is provided at a connection point between the upper arm 100U and the lower arm 100L, and outputs an alternating current from the external connection AC terminal 113 to external equipment (e.g., a motor). A capacitor or the like is connected to the direct-current power supply line in parallel with the upper and lower arms 100U and 100L.

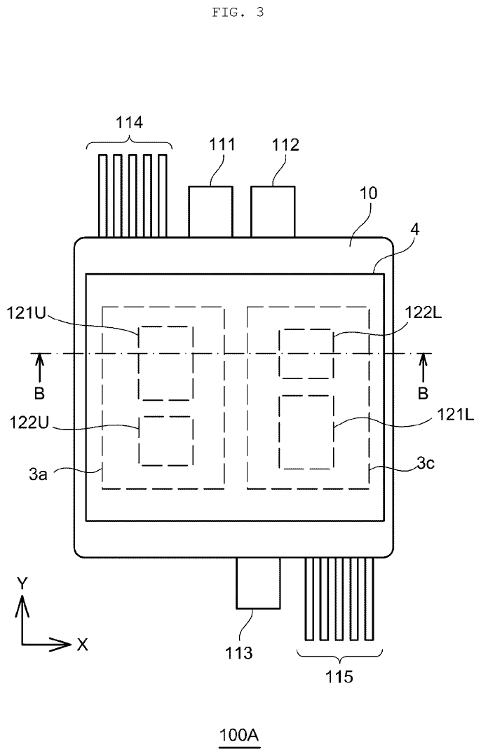

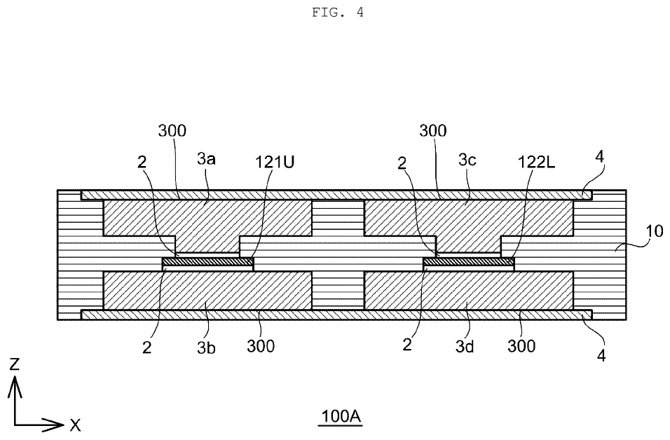

FIG. 3 is a plan view illustrating the external shape of the power module 100A. FIG. 4 is a cross-sectional view taken along line B-B of FIG. 3. The power semiconductor elements 121U and 121L, the diodes 122U and 122L, and the like of the power module 100A are sealed with a sealing resin 10 formed of an electrically insulating material. The external connection P terminal 111, the external connection N terminal 112, the external connection AC terminal 113, the upper arm control terminal 114, and the lower arm control terminal 115 are exposed from the sealing resin 10. An insulation layer 4 is arranged on both front and back surfaces of the power module 100A so as to be exposed from the sealing resin 10.

As illustrated in the cross-sectional view taken along line B-B of FIG. 4, a front surface electrode of the power semiconductor element 121U is joined to a conductor 3a by a joint material 2. A back surface electrode of the power semiconductor element 121U is connected to a conductor 3b by the joint material 2. Similarly, a front surface electrode of the diode 122L is joined to a conductor 3c by the joint material 2. A back surface electrode of the diode 122L is joined to a conductor 3d by the joint material 2. The conductors 3a to 3d are formed of, for example, copper, a copper alloy, aluminum, an aluminum alloy, or the like. The joint material 2 is formed of a solder material, a sintered material, or the like. Note that although not illustrated, the electrodes on the front and back surfaces of the diode 122U are joined to the conductors 3a and 3b similarly to the power semiconductor element 121U. The electrodes on the front and back surfaces of the power semiconductor element 121L are joined to the conductors 3c and 3d similarly to the diode 122L.

Each of the conductors 3a to 3d has an element joint surface and a heat dissipation surface 300 opposite to the element joint surface. The heat dissipation surfaces 300 of the conductors 3a and 3c are each provided with an insulation layer 4 that is thermally conductive. Similarly, the heat dissipation surfaces 300 of the conductors 3b and 3d are also each provided with the insulation layer 4. The insulation layer 4 thermally conducts heat generated from the semiconductor elements (121U, 1220, 121L, and 122U) to heat dissipation members (radiators 7a and 7b described later) arranged on both the front and back surfaces of the power module 100A, and is formed of a material having high thermal conductivity and a large withstand voltage. It is possible to use, for example, ceramics such as aluminum oxide (alumina), aluminum nitride, and silicon nitride, or an insulating sheet or an adhesive containing fine powder of them.

Returning to FIG. 1, the three power modules 100A, 100B, and 100C are arranged in a line in the longitudinal direction (X direction) of the semiconductor device 1. Each of the power modules 100A to 100C is arranged such that the terminals 111 to 115 protrude laterally in the Y direction of the semiconductor device 1.

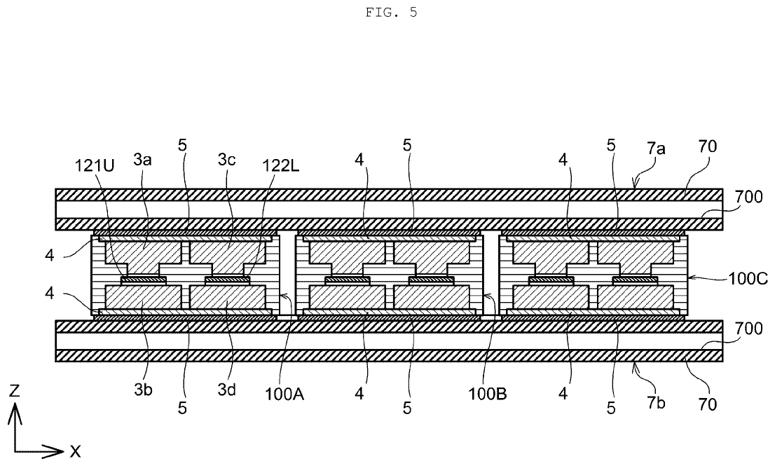

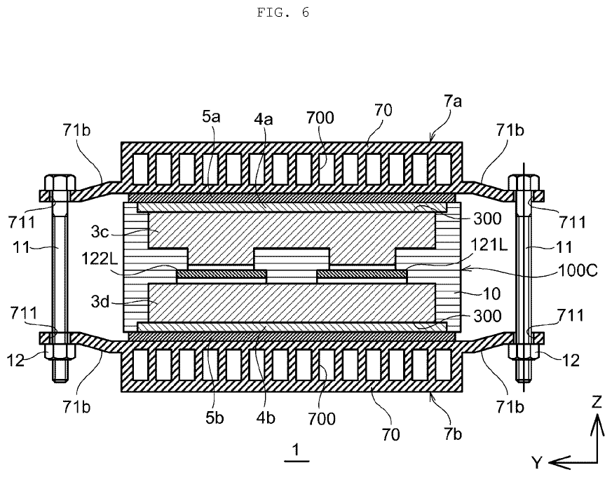

FIG. 5 is a cross-sectional view taken along line A-A of FIG. 1. FIG. 6 is a cross-sectional view taken along line C-C of FIG. 1. As illustrated in FIG. 5, the power modules 100A to 100C are sealed with the sealing resin 10 such that the insulation layer 4 covering the heat dissipation surfaces 300 of the conductors 3a to 3d are exposed to the surface (see FIG. 4). The surface of the insulation layer 4 exposed from the sealing resin 10 is provided with a thermal conduction layer 5. For the thermal conduction layer 5, a high thermal conduction member such as grease or thermal interface material (TIM) is used.

The radiators 7a and 7b are provided so as to sandwich the power modules 100A, 100B, and 100C provided with the thermal conduction layer 5. In the present embodiment, as the radiators 7a and 7b, a cooler including a flow path 700 through which a coolant flows in a main body portion 70 is used. As illustrated in FIG. 6, a plurality of the flow paths 700 extending in the longitudinal direction (X direction) are formed in the main body portions 70 of the radiators 7a and 7b.

As illustrated in FIG. 1, a plurality of the fixing flanges 71a and 71b arranged at predetermined intervals in the longitudinal direction of the radiator 7a are formed on a side surface in the y direction of the main body portion 70 of the radiator 7a. The fixing flanges 71a and 71b are fixing flanges having a cantilever shape, and are formed so as to protrude laterally (Y direction) from the main body portion 70. Although not visible in FIG. 1, the radiator 7b is provided on the back surface side of the power modules 100A to 100C. Also in the radiator 7b, the similar fixing flanges 71a and 71b are formed at positions opposing the fixing flanges 71a and 71b of the radiator 7a (see FIG. 6). The plurality of fixing flanges 71a and 71b have the identical thickness dimensions. However, regarding the width dimension, a width dimension W2 of the fixing flange 71b arranged at both ends in the longitudinal direction is set to be smaller than a width dimension W1 of the other fixing flange 71a arranged more inwardly in the longitudinal direction than both ends.

A through hole 711 through which a bolt 11 is inserted is formed in each of the fixing flanges 71a and 71b. As illustrated in FIG. 6, the fixing flanges 71a and 71b of the radiator 7a and the opposing fixing flanges 71a and 71b of the radiator 7b are coupled and fixed using the bolt 11 and a nut 12, whereby the radiators 7a and 7b are fixed to both the front and back surfaces of the power modules 100A to 100C arranged in a line.

The radiators 7a and 7b are formed of a member having thermal conductivity such as, for example, Cu, a Cu alloy, or a composite material such as Cu—C or Cu—CuO, or Al, an Al alloy, or a composite material such as AlSiC or Al—C. Heat generated in the power modules 100A to 100C is thermally conducted to the main body portions 70 of the radiators 7a and 7b via the insulation layer 4 and the thermal conduction layer 5, and is dissipated to the coolant flowing through the flow path 700.

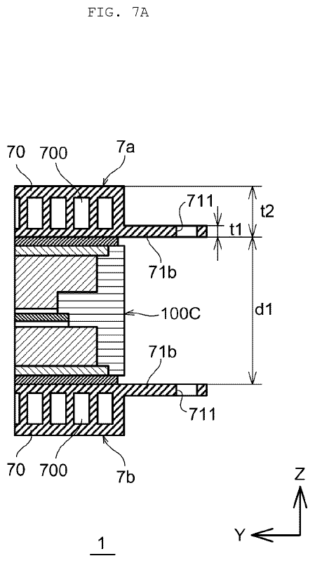

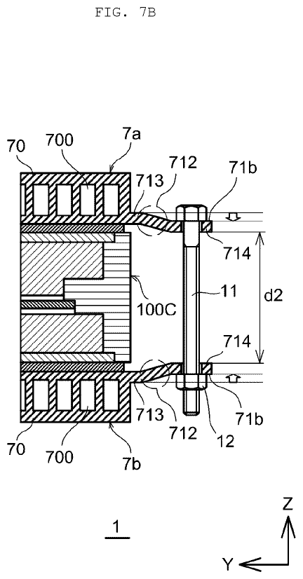

FIG. 7A is a view illustrating the shape of the fixing flange 71b before being coupled by the bolt 11 and the nut 12. FIG. 7B is a view illustrating the shape of the fixing flange 71b after being coupled. Note that although not visible in FIGS. 7A and 7B, the fixing flange 71a also has the same shape as the fixing flange 71b illustrated in FIGS. 7A and 7B.

In the radiators 7a and 7b, the thickness dimensions of the fixing flanges 71a and 71b are each set to be t1. The thickness dimension t1 of the fixing flanges 71a and 71b is set to be smaller than a thickness dimension t2 of the main body portion 70 in which the flow path 700 is formed. Therefore, when the pair of opposing fixing flanges 71b are coupled to each other by the bolt 11 and the nut 12 and the tightening torque of the bolt 11 is increased, the fixing flanges 71a and 71b having flexural rigidity relatively lower than that of the main body portions 70 are elastically deformed on the power module 100C side so as to approach each other as indicated by an arrow (see FIG. 7B). Here, the flexural rigidity is used as an index of deformability, but the second moment of area, a section modulus, or the like may be used as an index.

The main body portions 70 of the radiators 7a and 7b are pressed against the power modules 100A to 100C by the elastic force by elastic deformation of the fixing flanges 71a and 71b. In this manner, by applying the surface pressure between the radiators 7a and 7b and the power modules 100A to 100C, the thermal conduction efficiency from the power modules 100A to 100C to the radiators 7a and 7b is improved.

In the fixing state illustrated in FIG. 7B, an inter-surface distance d2 between the fixing flanges 71b at a part fixed with the bolt is smaller than an inter-surface distance d1 of the main body portion 70 where the flow paths 700 of the radiators 7a and 7b are formed (d2<d1). The same applies to the fixing flange 71a. That is, in the fixing state illustrated in FIG. 7B, a bent portion 712 (part surrounded by a broken line) that is deformed is generated between a root region 713 on the main body portion 70 side and a bolt fixing region 714 of the fixing flange 71b. Therefore, deformation of the main body portion 70 in which the flow paths 700 of the radiators 7a and 7b are formed is suppressed, and uniformity of the surface pressure with respect to the power module 100C can be obtained.

As illustrated in FIG. 1, the width dimension W2 of the fixing flange 71b arranged at both ends in the longitudinal direction among the plurality of the fixing flanges 71a and 71b arranged in the longitudinal direction of the radiators 7a and 7b is set to be smaller than the width dimension W1 of the fixing flange 71a arranged inside thereof in the longitudinal direction. That is, since the flexural rigidity of the fixing flange 71b is set to be smaller than the flexural rigidity of the fixing flange 71a, it is possible to prevent a curve of the main body portions 70 of the radiators 7a and 7b in the longitudinal direction in the fixing state.

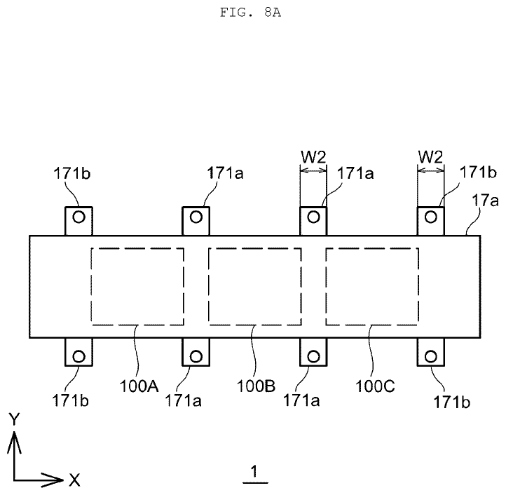

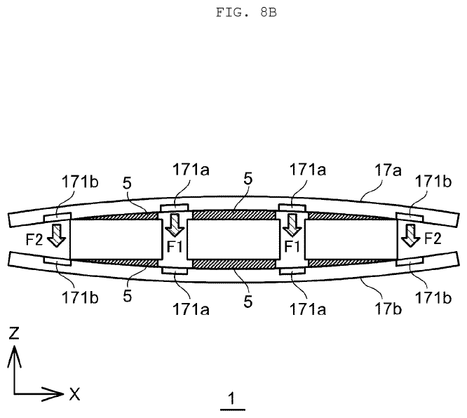

For example, a case where the width dimensions of a plurality of fixing flanges 171a and 171b provided along the longitudinal direction are all set to the identical value W2 as in radiators 17a and 17b illustrated in FIGS. 8A and 8B will be considered. That is, the thickness dimension and the width dimension of all of the fixing flanges 171a and 171b are set to t1 and W2, respectively. In this case, when the pair of fixing flanges 171a and 171b opposing each other in the Z direction are coupled and fixed, if the deformation amounts of the fixing flanges 171a and 171b are identical, an elastic force F1 of the fixing flange 171a and an elastic force F2 of the fixing flange 171b exerted on the radiator 17a are equal as F1=F2.

In this manner, when the elastic force F2 acting on the vicinity of both ends of the radiator 17a is equal to the elastic force F1 acting at the inside position, the radiator 17a is deformed so as to be curved convexly upward as illustrated in FIG. 8B. The same applies to the radiator 17b on the lower side, which is curved convexly downward. Therefore, the surface pressure applied from the radiators 17a and 17b to each of the power modules 100A to 100C is large at both ends in the longitudinal direction of the radiator and is small as approaching the center, and the heat dissipation performance in the longitudinal direction is uneven, and there is a concern that the heat dissipation performance may deteriorate in the power module near the center.

On the other hand, as illustrated in FIG. 1, by setting the width dimension W2 of the fixing flanges 71b at both ends to be smaller than the width dimension W1 of the fixing flange 71a, that is, by making the flexural rigidity of the fixing flange 71a to be larger than the flexural rigidity of the fixing flange 71b, even if the deformation amounts of the fixing flanges 71a and 71b in the coupling and fixing state are the same, the elastic force F2 of the fixing flange 71b can be made smaller than the elastic force F1 of the fixing flange 71a (F1>F2). As a result, bending deformation in the longitudinal direction of the main body portions 70 of the radiators 7a and 7b can be suppressed, and the surface pressure with respect to the plurality of power modules 100A to 100C arrayed in the longitudinal direction can be made uniform.

As a matter of course, even in the configuration of W1=W2 as illustrated in FIG. 8A, it is theoretically possible to suppress the bending deformation in the longitudinal direction of the main body portion 70 by not setting the identical deformation amounts when coupling and fixing the fixing flanges 71a and 71b and by managing the tightening torque of each bolt 11 such that the elastic forces F1 and F2 by the deformation satisfy F1>F2. However, the assembly work while managing the tightening torque of each bolt 11 becomes complicated, leading to deterioration of workability. On the other hand, when W1>W2 is set as illustrated in FIG. 1, and dimensions are managed so that the interval after coupling and fixing of all the fixing flanges 71a and 71b becomes d2 (see FIG. 7B), assembly workability is excellent and management is easy.

As described above, the present embodiment assumes a configuration in which the fixing flanges 71a and 71b are integrally formed in the main body portions 70 of the radiators 7a and 7b, and the fixing flanges 71a and 71b are elastically deformed to fix the radiators 7a and 7b. Due to that, it is possible to generate a compression surface pressure by pressing the radiators 7a and 7b against the power modules 100A to 100C without additionally providing a pressing member such as a leaf spring as in known cases. Then, it is possible to reduce the number of components and cost of the semiconductor device 1.

Furthermore, in the present embodiment, the width dimensions W1 and W2 are set such that W1>W2 is satisfied so that the flexural rigidity of the fixing flange 71b is smaller than the flexural rigidity of the fixing flange 71a. As a result, the surface pressures of the plurality of power modules 100A to 100C arranged side by side in the longitudinal direction of the radiator can be made uniform, and the heat dissipation performance can be improved.

### Modification 1

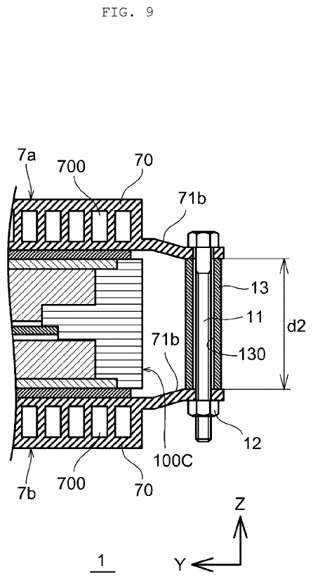

FIG. 9 is a view illustrating Modification 1 of the above-described embodiment. As illustrated in FIG. 7B, the intervals between the opposing fixing flanges 71a and 71b in the coupling and fixing state are all set to be d2. Therefore, in Modification 1, a spacer 13 as illustrated in FIG. 9 is provided in a bolt fixing portion so that the interval d2 can be easily managed. The shape of the spacer 13 is a columnar body whose cross-sectional shape is annular and length is d2. The spacer 13 is arranged between the fixing flanges 71a and 71b of the radiator 7a and the fixing flanges 71a and 71b of the radiator 7b, and the bolt 11 is inserted into a through hole 130 of the spacer 13 to tighten the nut 12. Then, the upper and lower fixing flanges 71a and 71b are deformed so as to approach each other, and the nut 12 is tightened until the spacer 13 is sandwiched between them, whereby the coupling and fixing are completed. Use of such the spacer 13 enables the interval between the upper and lower fixing flanges 71a and 71b to be easily set to an accurate value d2.

### Modification 2

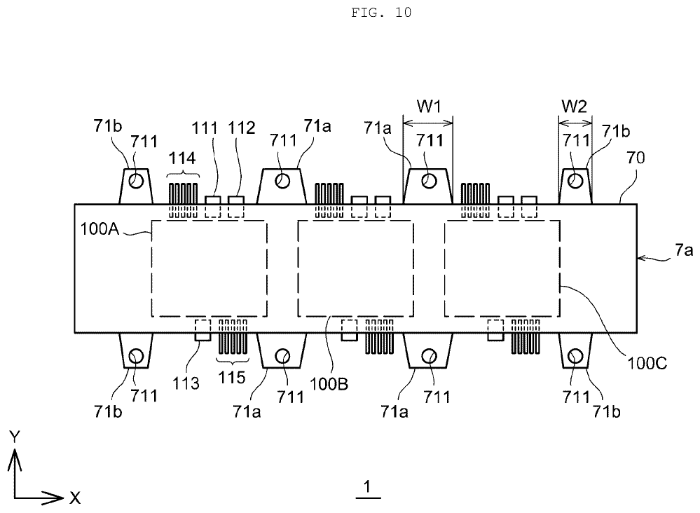

FIG. 10 is a view illustrating Modification 2. In Modification 2, the fixing flanges 71a and 71b are formed in a tapered shape in which the width dimensions of the root parts are W1 and W2 and the width dimensions decrease toward the tip end. In Modification 2, by giving the fixing flanges 71a and 71b the tapered shape in which the width dimensions of the root parts are W1 and W2 (<W1), it is possible to make the elastic force of the fixing flange 71b smaller than the elastic force of the fixing flange 71a, and it is possible to suppress curving deformation of the main body portions 70 of the radiators 7a and 7b as illustrated in FIG. 8B.

In Modification 2, by giving the fixing flanges 71a and 71b the tapered shape in which the width decreases from the root part to the tip end part, it is possible to reduce the weight of the radiators 7a and 7b. By giving the fixing flanges 71a and 71b the tapered shape, it is possible to further increase a space for pulling out the terminals 111 to 115 to the side of the semiconductor device 1, and the terminal connection work can be easily performed.

### Modification 3

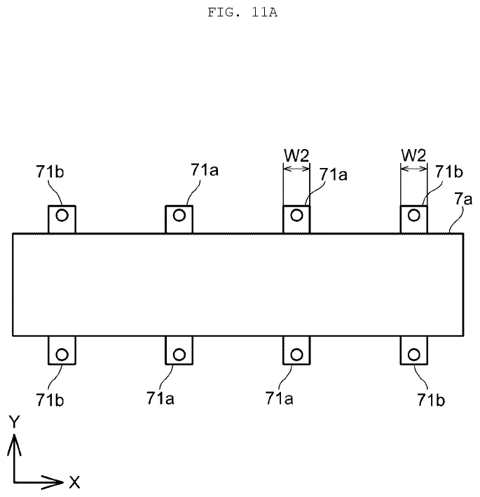

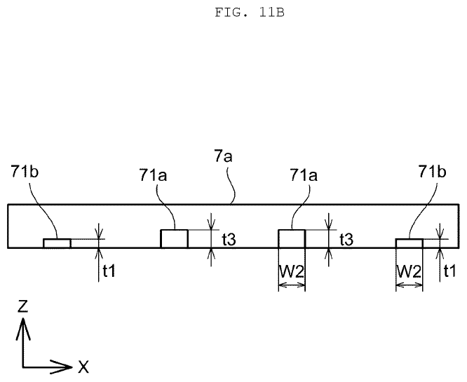

FIGS. 11A and 11B are views illustrating the radiator 7a in Modification 3. FIG. 11A is a plan view of the radiator 7a. FIG. 11B is a side view of the radiator 7a. Although not illustrated, the radiator 7b also has the same shape as the radiator 7a, and the configuration of the semiconductor device 1 other than the radiators 7a and 7b is the same as that of the above-described embodiment. In thee above-described embodiment and Modification 2, by making the width dimensions of the fixing flanges 71a and 71b different, the elastic force by deformation of the fixing flanges 71b at both ends is made smaller than the elastic force by deformation of the inner fixing flange 71a.

In Modification 3, as illustrated in FIG. 11A, the width dimensions of the fixing flanges 71a and 71b are set to be identical (W2), and the thickness dimensions are made different as illustrated in FIG. 11B, whereby the flexural rigidity of the fixing flanges 71b at both ends is made smaller than the flexural rigidity of the fixing flange 71a. As illustrated in FIG. 11B, the thickness dimension t1 of the fixing flange 71b is smaller than a thickness dimension t3 of the fixing flange 71a, and in the case of the identical deformation amount, the elastic force of the fixing flange 71b is smaller than the elastic force of the fixing flange 71a.

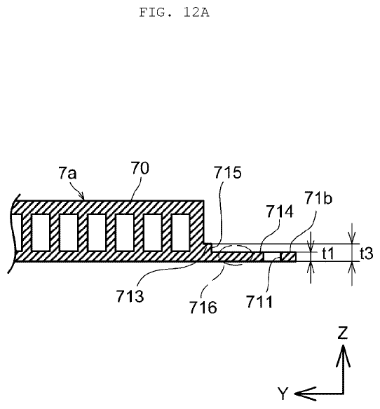

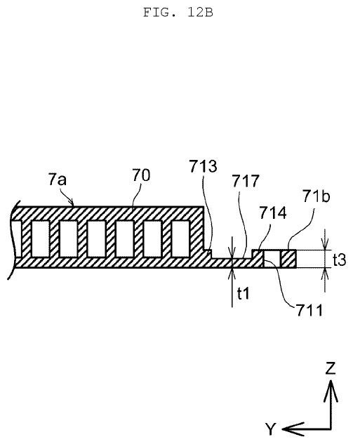

Note that in the example illustrated in FIGS. 11A and 11B, the thickness of the fixing flange 71b has the identical thickness dimension t1 from the flange root part to the tip end part, but may otherwise have a cross-sectional shape as illustrated in FIGS. 12A and 12B. FIGS. 12A and 12B are cross-sectional views of a part of the radiator 7a provided with the fixing flange 71b.

The fixing flange 71b illustrated in FIG. 12A is obtained by processing the other part except for a part of the root region of the flange part formed in the identical shape to the fixing flange 71a (thickness dimension t3) to have the thickness dimension t1 by press processing or the like. A step 715 is formed on the fixing flange 71b by press processing or the like. When the fixing flange 71b is coupled and fixed to the opposing fixing flange 71b, a thin portion 716 having the thickness dimension t1 is deformed. Therefore, at the time of deformation, an elastic force similar to that in the case of the fixing flange 71b illustrated in FIG. 11B is generated.

The fixing flange 71b illustrated in FIG. 12B is obtained by processing an intermediate part in the length direction of the flange part formed in the identical shape to the fixing flange 71a (thickness dimension t3) to have the thickness dimension t1 by press processing or the like. In the fixing flange 71b, a recess portion 717 having the thickness dimension t1 is formed by press processing or the like. When the fixing flange 71b is coupled and fixed to the opposing fixing flange 71b, the recess portion 717 is deformed, and an elastic force similar to that of the fixing flange 71b illustrated in FIG. 11B is generated.

### Modification 4

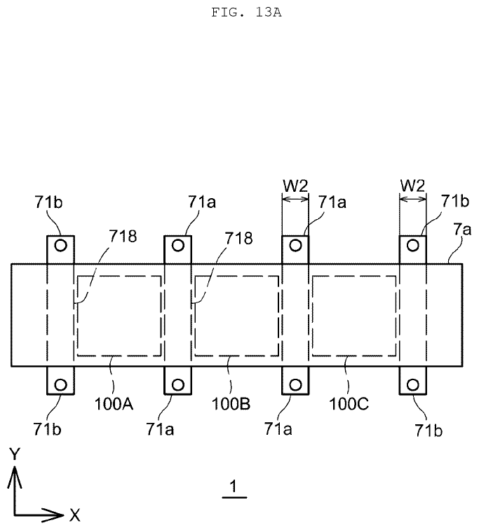

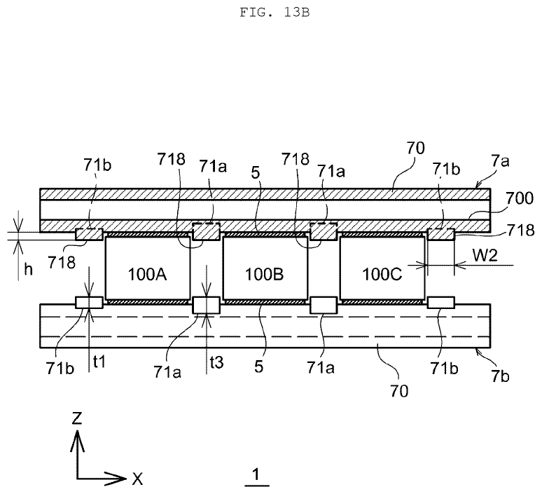

FIGS. 13A and 13B are views illustrating Modification 4. FIG. 13A is a plan view of the semiconductor device 1. FIG. 13B is a view of the semiconductor device 1 as viewed laterally, and is a cross-sectional view as for the radiator 7a. Note that illustration of the terminals 111 to 115 of the power modules 100A to 100C is omitted. Also in the case of Modification 4, similarly to the case of Modification 3 (see FIG. 11B), the width dimensions of the fixing flanges 71a and 71b are all set to the same value W2, the thickness dimension of the fixing flange 71a is set to be t3, and the thickness dimension of the fixing flange 71b is set to be t1 (<t3).

As illustrated in FIGS. 13A and 13B, a protrusion portion 718 extending in the Y direction (short direction of radiators 7a and 7b) is formed on surfaces of the radiators 7a and 7b opposing the power modules 100A to 100C. The height of the protrusion portion 718 is h, and the width dimension is W2, which is the same as that of the fixing flanges 71a and 71b. The power modules 100A to 100C are arranged between the protrusion portion 718 and the adjacent protrusion portion 718.

In the case of the radiators 7a and 7b illustrated in FIGS. 13A and 13B, the positions of the fixing flanges 71a and 71b in the radiator longitudinal direction (X direction) are set at the same position as the protrusion portion 718, and the surfaces of the fixing flanges 71a and 71b and the protrusion portion 718 on the power module side are on the identical surface. That is, the fixing flanges 71a and 71b are formed so as to be continuous with the protrusion portion 718. Of course, the protrusion portion 718 may be formed in the main body portions 70 of the radiators 7a and 7b of the above-described embodiment and Modifications 1 to 3.

By forming, on the main body portions 70 of the radiators 7a and 7b, the protrusion portion 718 extending in the Y direction, it is possible to increase the flexural rigidity for the deformation along the short direction (Y direction) of the main body portion 70 and to suppress the deformation of the main body portion 70 by the elastic force of the fixing flanges 71a and 71b. Furthermore, since the positioning of the power modules 100A to 100C in the X direction can be performed using the protrusion portion 718, the assembling workability can be improved.

Note that the position of the protrusion portion 718 in the longitudinal direction needs not be the identical to the positions of the fixing flanges 71a and 71b. In place of forming the protrusion portion 718 integrally with the main body portion 70 of the radiators 7a and 7b, a configuration may be adopted in which another member is joined to the main body portion 70 to form the protrusion portion 718.

### Modification 5

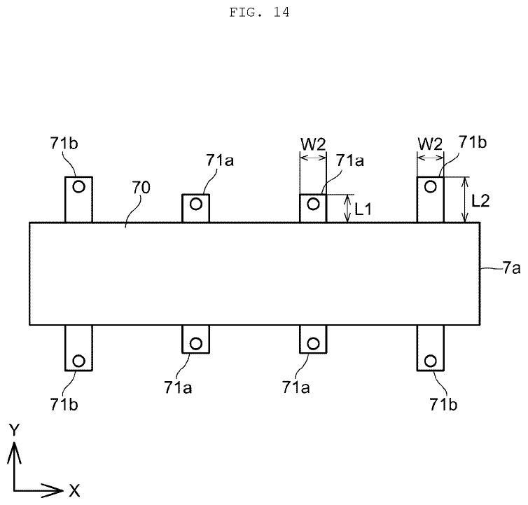

FIG. 14 is a view illustrating Modification 5. In the above-described embodiment and modifications, the width dimension and the thickness dimension of the fixing flanges 71a and 71b are made different, and the flexural rigidity of the fixing flange 71b is made smaller than the flexural rigidity of the fixing flange 71a. In Modification 5, as illustrated in FIG. 14, a length dimension L2 of the fixing flange 71b is set to be larger than a length dimension L1 of the fixing flange 71a, whereby the flexural rigidity of the fixing flange 71b is made smaller than the flexural rigidity of the fixing flange 71a.

### Modification 6

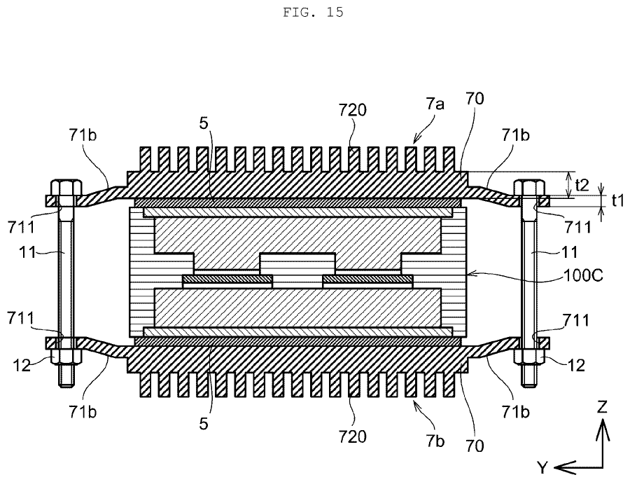

FIG. 15 is a view illustrating Modification 6. In the above-described embodiment and modifications, the main body portion 70 of each of the radiators 7a and 7b is provided with the plurality 41 flow paths 700 through which the coolant flows. On the other hand, in Modification 6, as illustrated in FIG. 15, the radiators 7a and 7b are configured to have a heat dissipation fin 720 on the surface side (surface opposite to the power module opposing surface) of the main body portion 70. Other configurations are similar to those of the radiators 7a and 7b illustrated in FIG. 6 of the above-described embodiment. In the example illustrated in FIG. 15, the heat dissipation fin 720 is a pin fin, but may be a straight fin or a corrugated fin.

For the member used for the radiators 7a and 7b, a member having good thermal conductivity is used, and for example, Cu, a Cu alloy, or a composite material such as Cu—C or Cu—CuO, or Al, an Al alloy, or a composite material such as AlSiC or Al—C is used. Also in the case of the radiators 7a and 7b including such the heat dissipation fin 720, the thickness dimension t1 of the fixing flanges 71a and 71b is set to be larger than the plate thickness t2 of the main body portion 70 such that the flexural rigidity of the main body portion 70 opposing the power modules 100A to 100C is larger than the flexural rigidity of the fixing flanges 71a and 71b.

### Modification 7

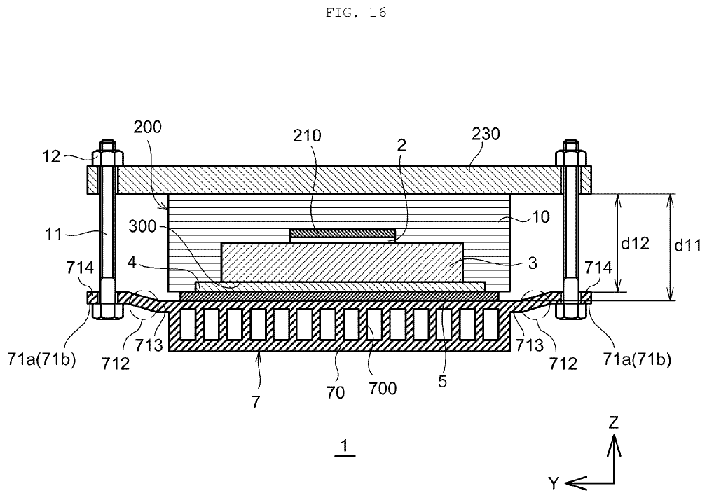

FIG. 16 is a view illustrating Modification 7. In the above-described embodiment and modifications, the power modules 100A to 100C are provided with the heat dissipation surfaces 300 on both the front and back surfaces, and the radiators 7a and 7b are provided on both the front and back surfaces of the power modules 100A to 100C. On the other hand, the semiconductor device 1 of Modification 7 is a semiconductor device having a one-side cooling structure including a radiator only on one side of the power module.

In a power module 200 provided in the semiconductor device 1 illustrated in FIG. 16, a back-surface-side electrode of a power semiconductor element 210 is joined to the conductor 3 by the joint material 2. The heat dissipation surface 300 of the conductor 3 is provided with the insulation layer 4 that is thermally conductive. The back surface side of the insulation layer 4 is exposed from the sealing resin 10, and the exposed surface is provided with the thermal conduction layer 5. The radiator 7 is provided on the back surface side of the power module 200 via the thermal conduction layer 5. The fixing flanges 71a and 71b of the radiator 7 are fixed by the bolt 11 and the nut 12 to a plate 230 provided on the front surface side of the power module 200.

Also in the case of Modification 7, similarly to the case of the above-described embodiment and modifications, the flexural rigidity of the fixing flanges 71b provided at both ends in the longitudinal direction of the radiator 7 is set to be smaller than the flexural rigidity of the fixing flanges 71a provided on the inside in the longitudinal direction. That is, since the elastic force of the fixing flange 71b in the fixing state is smaller than the elastic force of the fixing flange 71a, it is possible to prevent deformation of the radiator 7 as illustrated in FIG. 8B.

In the above-described embodiment and modifications, an example in which the sealing resin 10 includes the insulation layer 4 and a portion other than the surface of the insulation layer 4 is sealed has been described, but a structure in which the configuration of the conductors 3a to 3c and the conductor 3 is sealed by the sealing resin 10, and the heat dissipation surface 300 exposed from the sealing resin 10 is covered with the insulation layer 4 may be adopted.

In the above-described embodiment and modifications, a case where the power module is provided with a plurality of power semiconductor elements has been described as an example, but the present invention can be similarly applied to a semiconductor device including a power module having only one power semiconductor element.

According to the embodiment and modifications of the present invention described above, the following actions and effects are achieved.

(C1) As illustrated in FIGS. 1, 6, and the like, the semiconductor device 1 includes: the plurality of power modules 100A to 100C each incorporating the power semiconductor element 121L and the diode 122L and having the heat dissipation surface 300; the radiators 7a and 7b in thermal contact with the heat dissipation surfaces 300 of the plurality of power modules 100A to 100C arrayed in a line; and the bolt 11 and the nut 12 as fixing members that fix the radiators 7a and 7b so as to press the radiators 7a and 7b against the heat dissipation surfaces 300, in which the radiators 7a and 7b include the main body portions 70 pressed against the heat dissipation surfaces 300 of the power modules 100A to 100C and the plurality of the fixing flanges 71a and 71b each having a cantilever shape formed integrally with the main body portions 70 along the direction of the array of the plurality of power modules 100A to 100C and having flexural rigidity smaller than that of the main body portion 70, and the bolt 11 and the nut 12 fix the radiators 7a and 7b so as to elastically deform the fixing flanges 71a and 71b and press the main body portions 70 against the heat dissipation surfaces 300 of the power modules 100A to 100C by the elastic force of the fixing flanges 71a and 71b.

The fixing flanges 71a and 71b are formed in the main body portions 70 of the radiators 7a and 7b, and the main body portions 70 are pressed against the heat dissipation surfaces 300 of the power modules 100A to 100C by the elastic force when the fixing flanges 71a and 71b are elastically deformed. Therefore, as in known cases, the main body portions 70 of the radiators 7a and 7b can be pressed against the power module without separately providing a biasing member such as a spring plate. As a result, it is possible to reduce the number of components and cost of the semiconductor device.

(C2) In the above (C1), as illustrated in FIG. 7A and the like, by setting the thickness dimension t1 of the fixing flanges 71a and 71b to be smaller than the thickness dimension t2 of the main body portion 70, the flexural rigidity of the fixing flanges 71a and 71b is set to be smaller than the flexural rigidity of the main body portion 70.

(C3) In the above (C1), as illustrated in FIG. 10 and the like, the width dimensions W1 and W2 of the fixing flanges 71a and 71b are set to be smaller values as approaching the tip end of the cantilever shape. As a result, it is possible to increase the space for pulling out the terminals 111 to 115 provided in the power modules 100A to 100C to the side of the semiconductor device 1, and the terminal connection work can be easily performed.

(C4) In the above (C1), as illustrated in FIG. 7B and the like, the fixing flanges 71a and 71b of the radiators 7a and 7b fixed by the bolt 11 and the nut 12, which are fixing members, have the bent portion 712 by elastic deformation between the root region 713 having the cantilever shape and the fixing region 714 by the bolt 11. Since the flexural rigidity of the fixing flanges 71a and 71b is smaller than the flexural rigidity of the main body portion 70, the fixing flanges 71a and 71b are elastically deformed when fixed by the bolt, and the bent portion 712 is generated. The main body portion 70 is pressed in the power module direction by the elastic force of this bent portion 712.

(C5) In the above (C4), as illustrated in FIGS. 6, 7A, 7B, and the like, the heat dissipation surface 300 includes the first radiator 7a and the second radiator 7b provided on both the front and back surfaces in the thickness direction of the power modules 100A to 100C, the first radiator 7a being pressed against the heat dissipation surface 300 on the front surface side, and the second radiator 7b being pressed against the heat dissipation surface 300 on the back surface side, and the inter-surface distance d2 between the fixing region 714 of the fixing flanges 71a and 71b provided in the first radiator 7a and the fixing region 714 of the fixing flanges 71a and 71b provided in the second radiator 7b is set to be smaller than the inter-surface distance d1 between the first radiator 7a and the second radiator 7b. Therefore, in the fixing state, the radiators 7a and 7b are pressed in the direction of the heat dissipation surfaces 300 of the power modules 100A to 100C by the elastic force of the fixing flanges 71a and 71b that are deformed.

(C6) In the above (C4), as illustrated in FIG. 16 and the like, the plate 230 provided so as to abut on one surface in the thickness direction of the power module 200, the plate 230 to which the fixing flanges 71a and 71b are coupled and fixed by the bolt 11 and the nut 12 is further included, and the heat dissipation surface 300 against which the radiator 7 is pressed is provided on the other surface in the thickness direction of the power module 200, and an inter-surface distance d12 between the fixing region 714 of the fixing flanges 71a and 71b provided in the radiator 7 and the plate 230 is set to be smaller than an inter-surface distance d11 between the main body portion 70 of the radiator 7 and the plate 230. Therefore, in the fixing state, the radiator 7 is pressed in the direction of the heat dissipation surface 300 of the power module 200 by the elastic force of the fixing flanges 71a and 71b that are deformed.

(C7) In the above (C1), as illustrated in FIG. 1 and the like, the flexural rigidity of the fixing flange 71b arranged at both ends in the X direction among the plurality of the fixing flanges 71a and 71b provided along the direction (X direction) of the array of the power modules 100A to 100C is set to be smaller than the flexural rigidity of the other fixing flange 71a arranged inside. Therefore, in the fixing state, it is possible to prevent the main body portions 70 of the radiators 7a and 7b from being curved in the longitudinal direction.

(C8) In the above (C7), as illustrated in FIG. 1 and the like, the thickness dimension of each of the plurality of the fixing flanges 71a and 71b is equal, and the width dimension W2 of the fixing flange 71b arranged at both ends in the direction of the array of the power modules 100A to 100C is set to be smaller than the width dimension W1 of the other fixing flange 71a arranged inside. With such a configuration, the flexural rigidity of the fixing flange 71b is set to be smaller than the flexural rigidity of the fixing flange 71a.

(C9) In the above (C7), as illustrated in FIGS. 11A and 11B, the width dimension W2 of each of the plurality of the fixing flanges 71a and 71b is equal, and the thickness dimension t1 of the fixing flange 71b arranged at both ends in the direction of the array of the power modules 100A to 100C is set to be smaller than the thickness dimension t3 of the other fixing flange 71a arranged inside. With such a configuration, the flexural rigidity of the fixing flange 71b is set to be smaller than the flexural rigidity of the fixing flange 71a.

(C10) In the above (C7), as illustrated in FIG. 14 and the like, the width dimension W2 of each of the plurality of the fixing flanges 71a and 71b is equal, and the length dimension L2 of the fixing flange 71b arranged at both ends in the direction of the array of the power modules 100A to 100C is set to be larger than the length dimension L1 of the other fixing flange 71a arranged inside. With such a configuration, the flexural rigidity of the fixing flange 71b is set to be smaller than the flexural rigidity of the fixing flange 71a.

(C11) In the above (C7), as illustrated in FIGS. 12A, 12B, and the like, the fixing flange 71 b arranged at both ends in the direction of the array of the power modules 100A to 100C include the thin portion 716 and the recess portion 717 smaller in thickness dimension than the root region 713 between the root region 713 having the cantilever shape and the fixing region 714 by the bolt 11 and the nut 12. Therefore, the fixing flange 71b is bent at the part of the thin portion 716 and the recess portion 717, and is smaller in flexural rigidity than the fixing flange 71a having the thickness dimension t3.

(C12) In the above (C9), as illustrated in FIGS. 13A, 13B, and the like, the main body portion 70 includes the protrusion portion 718 extending in the direction (Y direction) orthogonal to the direction (X direction) of the array in the region where the power modules 100A to 100C do not oppose each other on the surfaces on the power modules 100A to 100C side, and the fixing flanges 71a and 71b are formed so as to be continuous with the protrusion portion 718. Since the protrusion portion 718 extending in the Y direction is provided in the main body portion 70, the flexural rigidity along the Y direction of the main body portion 70 is improved. The protrusion portion 718 can be used as a positioning portion when the power modules 100A and 100C are arranged, and assembly workability can be improved.

(C13) In the above (C1), as illustrated in FIG. 9 and the like, the spacer 13 that restricts, to the predetermined value d2, the deformation amounts of the fixing flanges 71a and 71b by the bolt 11 and the nut 12 is further included. Use of the spacer 13 enables the interval between the upper and lower fixing flanges 71a and 71b to be easily set to the accurate value d2, and workability can be improved.

Each embodiment and various modifications described above are merely examples, and the present invention is not limited to these contents and the above-described embodiment and various modifications may be combined as long as the features of the invention are not impaired. Although various embodiments and modifications have been described above, the present invention is not limited to these contents. Other aspects conceivable within the scope of the technical idea of the present invention are also included in the scope of the present invention.

### REFERENCE SIGNS LIST

1 semiconductor device
3, 3a to 3d conductor
7, 7a, 7b, 17a, 17b radiator
10 sealing resin
11 bolt
12 nut
13 spacer
70 main body portion
71a, 71b, 171a, 171b fixing flange
100, 100A to 100C, 200 power module
121U, 121L, 210 power semiconductor element
122U, 122L diode
230 plate
300 heat dissipation surface
712 bent portion
713 root region
714 fixing region
715 step
716 thin portion
717 recess portion
718 protrusion portion
720 heat dissipation fin

1. A semiconductor device, comprising:
a plurality of semiconductor modules each incorporating a power semiconductor element and having a heat dissipation surface;
a radiator in thermal contact with the heat dissipation surfaces of the plurality of semiconductor modules arrayed in a line; and
a fixing member that fixes the radiator so as to press the radiator against the heat dissipation surfaces,
wherein the radiator includes
a heat dissipation base portion pressed against the heat dissipation surfaces of the semiconductor modules, and
a plurality of fixing flange portions each having a cantilever shape formed along a direction of the array integrally with the heat dissipation base portion and having flexural rigidity smaller than flexural rigidity of the heat dissipation base, and
the fixing member fixes the radiator so as to elastically deform the fixing flange portion and press the heat dissipation base portion against the heat dissipation surfaces of the semiconductor modules by an elastic force of the fixing flange portion.

2. The semiconductor device according to claim 1,
wherein a thickness dimension of the fixing flange portion is set to be smaller than a thickness dimension of the heat dissipation base portion.

3. The semiconductor device according to claim 1,
wherein a width dimension of the fixing flange portion is set to a smaller value toward a tip end of the cantilever shape.

4. The semiconductor device according to claim 1,
wherein the fixing flange portion of the radiator fixed by the fixing member has a bent portion due to elastic deformation between a root region of the cantilever shape and a fixing region by the fixing member.

5. The semiconductor device according to claim 4,
wherein the heat dissipation surface includes a first radiator and a second radiator provided on both front and back surfaces in a thickness direction of the semiconductor module, the first radiator being pressed against the heat dissipation surface on a front surface side, and the second radiator being pressed against the heat dissipation surface on a back surface side, and
an inter-surface distance between the fixing region of the fixing flange portion provided in the first radiator and the fixing region of the fixing flange portion provided in the second radiator is set to be smaller than an inter-surface distance between the heat dissipation base portion of the first radiator and the heat dissipation base portion of the second radiator.

6. The semiconductor device according to claim 4, further comprising
a plate provided so as to abut on one surface in a thickness direction of the semiconductor module, the plate to which the fixing flange portion is coupled and fixed by the fixing member,
wherein the heat dissipation surface against which the radiator is pressed is provided on an other surface in the thickness direction of the semiconductor module, and
an inter-surface distance between the fixing region of the fixing flange portion provided in the radiator and the plate is set to be smaller than an inter-surface distance between the heat dissipation base portion of the radiator and the plate.

7. The semiconductor device according to claim 1,
wherein the flexural rigidity of the fixing flange portions arranged at both ends in the direction of the array among the plurality of fixing flange portions provided along the direction of the array is set to be smaller than the flexural rigidity of other fixing flange portions.

8. The semiconductor device according to claim 7,
wherein a thickness dimension of each of the plurality of fixing flange portions is equal, and a width dimension of each of the fixing flange portions arranged at both ends in the direction of the array is set to be smaller than a width dimension of each of the other fixing flange portions.

9. The semiconductor device according to claim 7,
wherein a width dimension of each of the plurality of fixing flange portions is equal, and a thickness dimension of each of the fixing flange portions arranged at both ends in the direction of the array is set to be smaller than a thickness dimension of each of the other fixing flange portions.

10. The semiconductor device according to claim 7,
wherein a width dimension of each of the plurality of fixing flange portions is equal, and a length dimension of each of the fixing flange portions arranged at both ends in the direction of the array is set to be smaller than a length dimension of each of the other fixing flange portions.

11. The semiconductor device according to claim 7,
wherein the fixing flange portions arranged at both ends in the direction of the array include a thin portion smaller in thickness dimension than the root region between a root region having the cantilever shape and a fixing region by the fixing member.

12. The semiconductor device according to claim 9,
wherein the heat dissipation base portion includes a plurality of protrusion portions extending in a direction orthogonal to the direction of the array in a region where the semiconductor modules do not oppose each other on a surface on a semiconductor module side, and
the fixing flange portion is formed so as to be continuous with the protrusion portions.

13. The semiconductor device according to claim 1, further comprising:
a restriction portion that restricts, to a predetermined value, a deformation amount of the fixing flange portions by the fixing member.
